(19) United States
(12) Patent Application Publication
(10) Pub. No.: US 2014/0239428 A1
(43) Pub. Date: Aug. 28, 2014

(54) CHIP ARRANGEMENT AND A METHOD FOR MANUFACTURING A CHIP ARRANGEMENT

(71) Applicant: INFINEON TECHNOLOGIES AG, Neubiberg (DE)

(72) Inventors: Frank Pueschner, Kelheim (DE); Juergen Hoegerl, Regensburg (DE); Peter Stampka, Burglengenfeld (DE)

(73) Assignee: INFINEON TECHNOLOGIES AG, Neubiberg (DE)

(21) Appl. No.: 13/779,828

(22) Filed: Feb. 28, 2013

(51) Int. Cl. H01L 31/02; H01L 31/18

(52) U.S. Cl. CPC H01L 31/02; H01L 31/18
USPC 257/428; 438/64; 257/773

(57) ABSTRACT

According to various embodiments, a chip arrangement may be provided, the chip arrangement including: a chip; an antenna structure disposed over a first side of the chip, wherein the antenna structure may include an antenna being electrically conductively coupled to the chip; and a reinforcement structure, wherein the reinforcement structure supports the chip to increase the stability of the chip arrangement.

### TECHNICAL FIELD

Various embodiments relate generally to a chip arrangement and a method for manufacturing a chip arrangement.

### BACKGROUND

In general, an integrated circuit or a chip may be included in small housings usually made of plastic material, so called smart cards, chip cards, or integrated circuit cards. There may be a huge number of applications including for example personal identification. A chip card may include a contact pad structure for electrically connecting the chip card to an external device, e.g. to a card reader. Among the different types of smart cards, there are contactless smart cards such that the card data exchange and the power supply of the card may be realized using induction technology, e.g. radio frequency. The technical requirements for a chip, a chip package or a chip arrangement may also consider a mechanical load the chip may be subjected to. In a common approach, a chip, a chip package or a chip arrangement may have a thickness which may allow a bending or a deformation of the chip, the chip package or the chip arrangement without breaking or physically damaging the bulk silicon of the chip.

### SUMMARY

According to various embodiments, a chip arrangement is provided, the chip arrangement including: a chip; an antenna structure disposed over a first side of the chip, wherein the antenna structure include an antenna being electrically conductively coupled to the chip; and a reinforcement structure supporting the chip to increase the stability of the chip arrangement.

### BRIEF DESCRIPTION OF THE DRAWINGS

In the drawings, like reference characters generally refer to the same parts throughout the different views. The drawings are not necessarily to scale, emphasis instead generally being placed upon illustrating the principles of the invention. In the following description, various embodiments of the invention are described with reference to the following drawings, in which:

FIG. 1A and FIG. 1B respectively show a cross sectional view of a chip arrangement schematically, according to various embodiments;

FIG. 2A schematically shows a cross sectional view of a chip arrangement, according to various embodiments;

FIG. 2B schematically shows a perspective view of a chip arrangement, according to various embodiments;

FIG. 2C and FIG. 2D respectively show a cross sectional view of a chip arrangement schematically, according to various embodiments;

FIG. 2E schematically shows a cross sectional view of a part of a chip arrangement in detail, according to various embodiments;

FIG. 3A and FIG. 3B respectively show a cross sectional view of a chip arrangement schematically, according to various embodiments;

FIG. 4 shows a flow diagram of a method for manufacturing a chip arrangement, according to various embodiments;

FIG. 5A to FIG. 5E respectively shows a cross sectional view of a chip arrangement a various processing stages within the manufacturing process schematically, according to various embodiments;

FIG. 6A and FIG. 6B respectively show a cross sectional view of a chip arrangement schematically, according to various embodiments;

FIG. 7 schematically shows a cross sectional view of a chip arrangement, according to various embodiments;

FIG. 8A and FIG. 8B respectively show a cross sectional view of a chip arrangement schematically, according to various embodiments;

FIG. 9 shows schematically a perspective view of a chip arrangement, according to various embodiments;

FIG. 10 shows schematically a perspective view of a chip arrangement, according to various embodiments;

FIG. 11 shows schematically a perspective view of a testing device for a chip arrangement;

FIG. 12 shows schematically a perspective view of a solder type chip arrangement, according to various embodiments;

FIG. 13 shows schematically a perspective view of a glue type chip arrangement, according to various embodiments;

### DESCRIPTION

The following detailed description refers to the accompanying drawings that show, by way of illustration, specific details and embodiments in which the invention may be practiced.

The word “exemplary” is used herein to mean “serving as an example, instance, or illustration”. Any embodiment or design described herein as “exemplary” is not necessarily to be construed as preferred or advantageous over other embodiments or designs.

The word “over” used with regards to a deposited material formed “over” a side or surface may be used herein to mean that the deposited material may be formed “directly on”, e.g. in direct contact with, the implied side or surface. The word “over” used with regards to a deposited material formed “over” a side or surface, may be used herein to mean that the deposited material may be formed “indirectly on” the implied side or surface with one or more additional layers being arranged between the implied side or surface and the deposited material.

The words “coupled or connected” used with regards to a first member being “coupled or connected” with a second member, may be used herein to mean that the first member may be “directly mechanically connected” with the second member or “indirectly mechanically connected” with the second member, wherein an additional member or more than one additional members may be arranged in between of the first and the second member such that the additional member or the more than one additional members may provide the physical connection. The words “ electrically coupled or electrically connected ” or “electrically conductively coupled” used with regards to a first member being “electrically coupled” or “electrically conductively coupled” with a second member, may be used herein to mean that the first member may be “directly electrically connected” or “directly electrically conductively connected” with the second member or “indirectly electrically connected” or “indirectly electrically conductively connected” with the second member, wherein an additional member or more than one additional members may be arranged in between the first and the second member such that the additional member or the more than one additional members may provide the electrical connection or the electrically conductively connection.

Using flexible materials may allow providing a chip arrangement, a chip package, or a chip module, which may be robust referring to a mechanical load, since a flexible chip arrangement may compensate mechanical stress such that the chip or other components included in the chip package may not break due to the mechanical stress. Therefore, the chip arrangement may be provided using thin or ultra-thin chip (e.g. having a thickness equal or less than 100 μm). The silicon bulk material of the chip may provide excellent package breakage strength due to its flexibility. A chip arrangement may include various other components, e.g. metallization layers or metallization structures or dielectric layers or regions including dielectric material, providing the electrical functionality of the chip (and therefore also the electrical functionality of the chip arrangement), wherein these other components may reduce the stability of the chip arrangement, since these components (metallization layers or dielectric layers) may have a lower flexibility and therefore a higher vulnerability to mechanical stress. Referring to this, metallization layers or dielectric layers may further be subjected to an internal mechanical strain due to the manufacturing process, since for example the thermal expansion coefficients of the used materials (e.g. a metal (copper), e.g. a nitride (silicon nitride), e.g. an oxide (silicon oxide)) may differ from each other. However, since the mechanical properties of the silicon bulk of the chip may be substantially defined by the thickness of the chip, and chips with a lower thickness may have a higher flexibility and therefore chips with a lower thickness may withstand a higher mechanical load, before the chip may break or the chip may be destroyed, and on the other hand, if the chip may have a high flexibility, the metallization of the chip or other components may lose their functionality, despite the chip itself may be not destroyed. To improve the resistibility of the metallization of the chip or other components like dielectric layers, the chip may be reinforced increasing the stiffness of the chip or the chip arrangement.

Therefore, to provide an optimal stability of a chip arrangement or a chip package to a mechanical load, the stiffness of a chip arrangement may be balanced with the flexibility of the chip or the chip arrangement to prevent on one hand the breaking of the silicon bulk of the chip and on the other hand to protect the metallization and the dielectric regions.

According to various embodiments, the flexibility of a chip may be provided by using a thin or ultra-thin silicon bulk chip, e.g. having a thickness in the range from about 30 μm about to about 100 μm. According to various embodiments, the stiffness of a chip arrangement to protect or support the chip may be provided by a reinforcement structure, which may be mechanically or physically coupled to the chip.

According to various embodiments, a chip arrangement is provided having an optimal balance of the mechanical properties of the components of the chip arrangement such that the chip arrangement may withstand a mechanical load without losing the functionality.

According to various embodiments, a chip arrangement may include a chip; an antenna structure disposed over a first side of the chip, wherein the antenna structure may include an antenna being electrically conductively coupled to the chip and a reinforcement structure, which may optionally be coupled to the antenna structure. The reinforcement structure may support the chip to increase the stability of the chip arrangement.

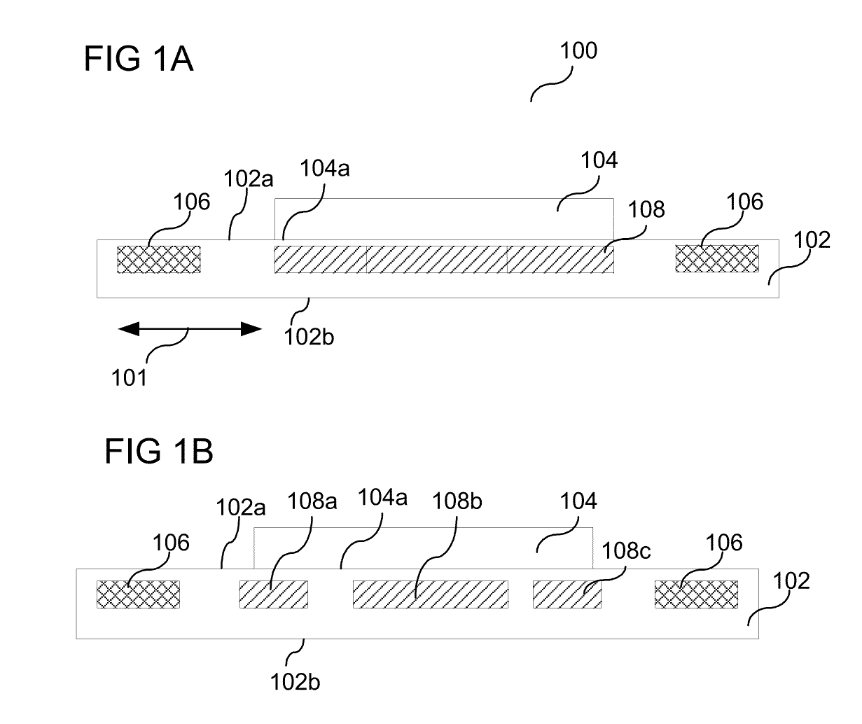

FIG. 1A shows a cross sectional view of a chip arrangement 100, according to various embodiments, including an antenna structure 102, and a chip 104, wherein the antenna structure 102 may include an antenna 106 and a reinforcement structure 108. According to various embodiments, the chip 104 may be arranged over a first side 102a of the antenna structure 102, wherein the chip 104 may be supported by the reinforcement structure 108. According to various embodiments, the chip 104 may be arranged over a second side 102b of the antenna structure 102, as shown in FIG. 1A, wherein the chip 104 may be supported by the reinforcement structure 108. According to various embodiments, the chip may be arranged above or below the antenna structure 102, which means the chip 104 may be attached with the chip side 104a of the chip 104 at the first side 102a of the antenna structure 102 or at the second side 102b of the antenna structure 102, wherein an additional material may be arranged between the chip 104 and the antenna structure 102, as will described in more detail below, e.g. such that the chip 104 may be indirectly coupled to the antenna structure 102.

According to various embodiments, the lateral extension of the chip 104, e.g. the extension along the lateral direction 101, as shown in FIG. 1A, may be larger than the lateral extension of the reinforcement structure 108, such that the reinforcement structure 108 may create a reinforced region, wherein the chip 104 may be positioned or arranged in or over the reinforced region, e.g. the chip 104 may be positioned or arranged completely within the reinforced region (e.g. the chip 104 may not laterally extend further than the reinforced region). According to various embodiments, the lateral extension of the chip 104, e.g. the extension along the lateral direction 101, as shown in FIG. 1A, may be smaller than the lateral extension of the reinforcement structure 108, such that the reinforcement structure 108 may create a reinforced region, wherein the chip 104 may be substantially arranged within the reinforced region, e.g. the chip 104 may be positioned or arranged within the reinforced region such that the reinforcement structure 108 may provide a sufficient protection to the chip 104 (e.g. the chip 104 may laterally extend further than the reinforced region, wherein the reinforcement structure 108 nevertheless may support the chip 104).

According to various embodiments, the lateral extension of the chip 104, e.g. the extension along the lateral direction 101, as shown in FIG. 1A, may be equal to the lateral extension of the reinforcement structure 108, such that the reinforcement structure 108 may create a reinforced region, wherein the chip 104 may be positioned or arranged at least one of over or below the reinforced region, wherein the chip 104 and reinforcement structure 108 may be superposed (e.g. the chip 104 may not laterally extend further than the reinforced region and may have the same lateral extension as the reinforced region).

According to various embodiments, the chip 104 may be disposed (e.g. arranged or positioned) over the reinforcement structure 108, as shown in FIG. 1A.

According to various embodiments, the chip may be disposed below the reinforcement structure, not shown in figures. In other words, the chip may be attached to a first side of an antenna carrier, wherein the antenna carrier may provide the support for the antenna, and the reinforcement structure supporting the chip may be arranged on a second side of the antenna carrier, opposite to the first side of the antenna carrier, as described before with reference to FIG. 1A.

According to various embodiments, as show in FIG. 1B, the reinforcement structure 108 may include more than one reinforcement structure element, e.g. three reinforcement structure elements 108a, 108b, 108c, as shown in FIG. 1B, e.g. more than three, e.g. four, e.g. five, e.g. six, e.g. seven, e.g. eight, e.g. nine, e.g. ten, or even more than ten.

According to various embodiments, the chip 104 may have a direct contact to the reinforcement structure 108 or to the reinforcement structure elements 108a, 108b, and 108c. According to various embodiments, the chip 104 may have a direct electrical contact to the reinforcement structure 108 or to at least some of the reinforcement structure elements (e.g. to the reinforcement structure elements 108a, 108c as shown in FIG. 1B). According to various embodiments, the chip 104 may have an indirect contact to the reinforcement structure 108 or to the reinforcement structure elements 108a, 108b, and 108c. According to various embodiments, the chip 104 may have an indirect electrical contact to the reinforcement structure 108 or to at least some of the reinforcement structure elements (e.g. to the reinforcement structure elements 108a, 108c as shown in FIG. 1B). According to various embodiments, an indirect contact may include one or more members in between the chip 104 and the reinforcement structure 108 providing the electrical connection.

According to various embodiments, the chip 104 may have a direct or an indirect electrically conductive connection to the antenna 106. According to various embodiments, the chip 104 may be indirectly electrically conductively coupled to the antenna 106, e.g. via the reinforcement structure 108 or the reinforcement structure elements 108a, 108c. According to various embodiments, at least a part of the reinforcement structure elements may provide an additional functionality, e.g. reinforcement structure elements 108a and 108c may provide at least a part of an electrically conductive connection between the antenna 106 and the chip 104. Referring to this, the reinforcement structure elements 108a and 108c may include an electrically conductive material, e.g. to provide an electrically conductive connection.

According to various embodiments, at least two reinforcement structure elements may be separated from each other, e.g. having no electrical connection between each other, or e.g. being spatially separated from each other by an additional material or by a gap. According to various embodiments, at least a part of the reinforcement structure elements, e.g. reinforcement structure elements 108a, 108c may be arranged electrically isolated from the reinforcement structure element 108b.

According to various embodiments, a first part of reinforcement structure (e.g. reinforcement structure elements 108a, 108c) may provide an electrically conductive connection between the chip 104 and another component of the chip arrangement 100 and a second part of the reinforcement structure (e.g. reinforcement structure element 108b) may provide a reinforced region to support the chip 104 or a mechanical stabilization to protect the chip, e.g. protect the chip from a mechanical load being subjected to the chip arrangement. Therefore, according to various embodiments, the chip 104 may have chip contacts arranged on the side of the chip facing the reinforcement structure 108 or the reinforcement structure elements 108a, 108c. Further, according to various embodiments, the chip contacts may be positioned on the side of the chip facing the reinforcement structure 108 to mate with the reinforcement structure elements 108a, 108c, or to mate with a contact pad or a plurality of contact pads in the side of the antenna structure 102 facing the chip. According to various embodiments, the antenna structure 102 may include a metallization to electrically connect the chip 104 with at least one of the reinforcement structure 108, the reinforcement structure elements 108a, 108c, the antenna 106, and with any other additional component included in the chip arrangement 100 if desired.

Referring to FIG. 1A and FIG. 1B, the reinforcement structure 108 may be arranged in the same layer as the antenna 106, according to various embodiments.

Referring to FIG. 1A and FIG. 1B, according to various embodiments, the reinforcement structure 108 or the reinforcement structure elements 108a, 108b, 108c may include or may consist of at least one of the following materials: a metal, a metal alloy, a metallic material, a metallic compound, an electrically conductive material, copper, a copper alloy, aluminum, an aluminum alloy, an aluminum-silicon alloy, titanium, gold, silver, platinum, nickel, zinc. According to various embodiments, the reinforcement structure 108 or the reinforcement structure elements 108a, 108b, 108c may include copper. According to various embodiments, the reinforcement structure 108 or the reinforcement structure elements 108a, 108b, 108c may consist of or include copper. According to various embodiments, the reinforcement structure 108 or the reinforcement structure elements 108a, 108b, 108c may include a material layer, e.g. a copper layer 108.

Referring to FIG. 1A and FIG. 1B, according to various embodiments, the antenna 106 may include or may consist of at least one of the following materials: a metal, a metal alloy, a metallic material, a metallic compound, an electrically conductive material, copper, a copper alloy, aluminum, an aluminum alloy, an aluminum-silicon alloy, titanium, gold, silver, platinum, nickel, zinc. According to various embodiments, the antenna 106 may include copper. According to various embodiments, the antenna 106 may consist of copper. According to various embodiments, the antenna 106 may include a patterned material layer, e.g. a patterned copper layer 108 (e.g. provided by using a copper etch technology).

According to various embodiments, the antenna 106 and the reinforcement structure 108 (or the reinforcement structure elements 108a, 108b, 108c) may include or may consist of the same material, selected from the group of materials as described above. According to various embodiments, the antenna 106 and the reinforcement structure 108 (or the reinforcement structure elements 108a, 108b, 108c) may include or may consist of copper.

According to various embodiments, as described in detail in the following, the antenna structure may include a carrier, an antenna and a reinforcement structure, wherein the antenna and the reinforcement structure may be provided on a side of the carrier. According to various embodiments, the chip may be attached to the side of the carrier including the antenna and the reinforcement structure; that means that the antenna and the reinforcement structure may face in the direction of the chip.

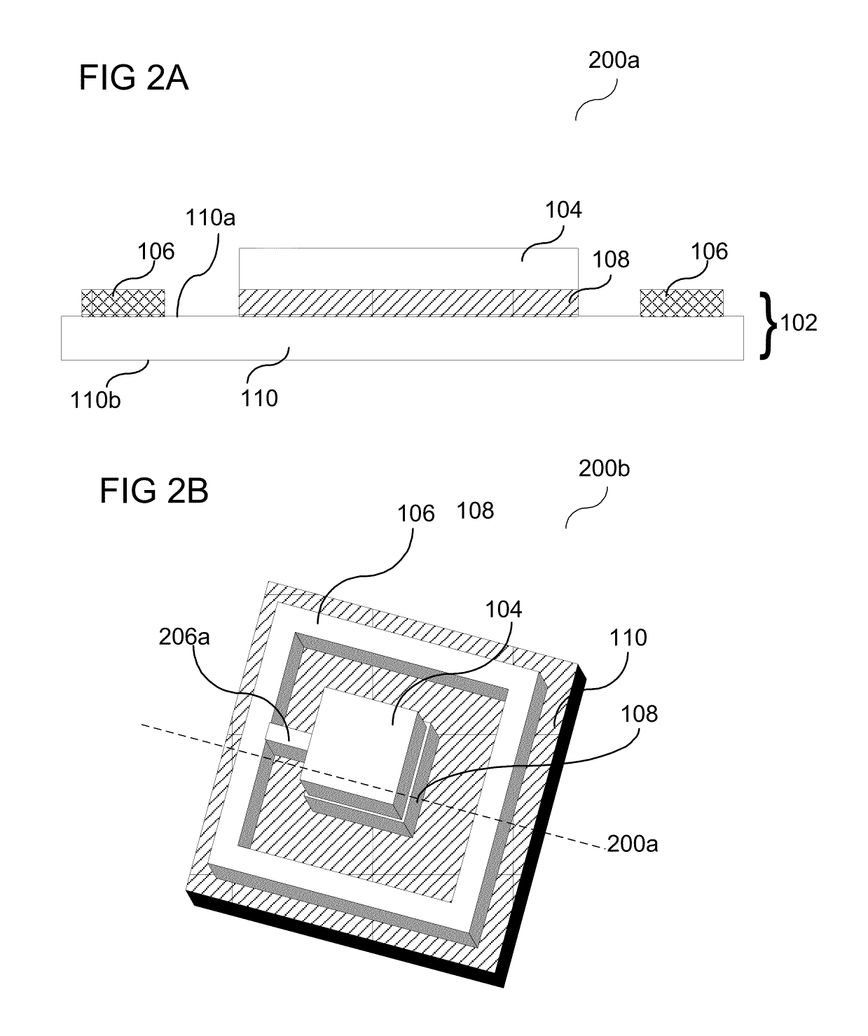

According to various embodiments, FIG. 2A shows a cross sectional view 200a of a chip arrangement 100, in analogy to the chip arrangement, as described referring to FIG. 1A and FIG. 1B, wherein an antenna 106 and a reinforcement structure 108 may be provided on a carrier 110 (antenna 106, reinforcement structure 108, and carrier 110 may be regarded as an antenna structure 102), and wherein a chip 104 may be coupled to the reinforcement structure 108 (and therefore, the chip 104 may be regarded as to be coupled to the antenna structure 102). According to various embodiments, the antenna 106, the reinforcement structure 108, and the chip 104 may be arranged on the same side of the carrier 110. According to various embodiments, the chip 104 may be electrically conductively coupled to the antenna 106, e.g. via an electrical connection 206a, as schematically shown in FIG. 2B.

FIG. 2B schematically shows a perspective view of the chip arrangement 100 as illustrated for example in FIG. 2A, according to various embodiments.

According to various embodiments, FIG. 2C shows a cross sectional view of a chip arrangement 100, in analogy to the chip arrangement as described referring to FIG. 1A, FIG. 1B, FIG. 2A and FIG. 2B, wherein an additional layer 202 may be arranged between the chip 104 and the carrier 110. According to various embodiments, the additional layer 202 may provide a physical connection between the chip 104 and the carrier 110. According to various embodiments, the additional layer 202 may provide at least a part of an electrically conductive connection between the chip 104 and the antenna 106 (or e.g. at least a part of the additional layer 202 may provide an electrically conductive connection between the chip 104 and the antenna 106, as shown in FIG. 2D).

According to various embodiments, the additional layer 202 may be arranged between a first side 204a of the chip 104 and a first side 208a of the reinforcement structure 108. According to another embodiment, the additional layer 202 may be also regarded as a part of the reinforcement structure 108, e.g. arranged between the chip 104 and the carrier 110.

According to various embodiments, FIG. 2D shows a cross sectional view of a chip arrangement 100, in analogy to the chip arrangement as described before, wherein a plurality of additional layer structure elements 202a, 202b, 202c may be arranged between the chip 104 and the carrier 110. According to various embodiments, the number of additional layer structure elements may be the same as the number of reinforcement structure elements 108a, 108b, 108c, as described referring to FIG. 1B. According to various embodiments, the chip 104 may have a direct or an indirect electrically conductive connection to the antenna 106. According to various embodiments, the chip 104 may be indirectly electrically conductively coupled to the antenna 106, e.g. by including the reinforcement structure 108 or the reinforcement structure elements. According to various embodiments, at least a part of the reinforcement structure elements and the additional layer structure elements may provide an additional functionality, e.g. reinforcement structure elements 108a and 108c and additional layer structure elements 202a and 202c may provide at least a part of an electrically conductive connection between the antenna 106 and the chip 104. Referring to this, the reinforcement structure elements 108a and 108c and the additional layer structure elements 202a and 202c may include an electrically conductive material, e.g. to provide an electrically conductive connection.

According to various embodiments, at least two reinforcement structure elements 108a, 108b and at least two additional layer structure elements may be separated from each other (e.g. additional layer structure elements 202a and 202b, or 202b and 202c), e.g. having no electrical connection between each other, or e.g. being spatially separated from each other by an additional material or by a gap 209. According to various embodiments, the reinforcement structure elements 108a, 108c and additional layer structure elements 202a, 202c may be arranged electrically isolated from the reinforcement structure element 108b and the additional layer structure element 202b, as shown in FIG. 2D. According to various embodiments, the reinforcement structure elements 108a, 108c and additional layer structure elements 202a, 202c may be at least a part of the electrically conductive connection between the chip 104 and the antenna 106, wherein for example the reinforcement structure elements 108a, 108c and additional layer structure elements 202a, 202c may further function as a part of the reinforcement structure 108 at the same time.

According to various embodiments, a first part of reinforcement structure and the additional layer, e.g. the reinforcement structure element 108a, 108c and additional layer structure element 202a, 202c, may provide an electrically conductive connection between the chip 104 and another component of the chip arrangement 100 (e.g. to an antenna or to a contact pad) and a second part of the reinforcement structure and the additional layer, e.g. reinforcement structure element 108b and additional layer structure element 202b, may provide a reinforced region to support the chip 104 or a mechanical stabilization to protect the chip 104, e.g. protect the chip from a mechanical load being subjected to the chip arrangement. In other words, the chip 104 may be attached to the reinforcement structure 108, wherein the reinforcement structure 108 may provide at least a part of an electrically conductive connection between the chip 104 and the antenna, wherein the reinforcement structure 108 may also provide the mechanical stability to protect the chip 104 from damage or destruction by a mechanical load.

According to various embodiments, the additional layer 202 or the additional layer structure elements 202a, 202b, 202c may include a solder structure 203, as shown in FIG. 2E. According to various embodiments, the additional layer 202 or the additional layer structure elements 202a, 202b, 202c may include a glue structure 205, as shown in FIG. 2E.

According to various embodiments, the solder structure 203 may include a first region 210a, e.g. a reinforcement structure 108, a second region 212a, e.g. including a solder material, and a third region 214a, e.g. including a metal or a metal alloy. According to various embodiments, the first region 210a may have the same properties, the same functionalities and/or the same features as the reinforcement structure 108 as already described. According to various embodiments, the second region 212a may be a solder layer to mechanically connect the chip 104 to the carrier 110. According to various embodiments, the second region 212a may be a solder layer to electrically connect the chip 104 to the antenna 106. According to various embodiments, the second region 212a may be a solder layer to mechanically and electrically connect the chip 104 to the antenna structure 102. The solder layer 212a may include a solder material, e.g. at least one material of the following group of materials: a metal, a metal alloy, silver, nickel, tin, or any other suitable solder material. According to various embodiments, the second region 212a may include an electrically conductive material, e.g. to provide an electrical connection between the first region 210a of the solder structure 203 and third region 214a of the solder structure 203. According to various embodiments, the solder layer 212a may also provide a reinforcement to support the chip; therefore, the second region 212a or the solder layer 212a may also be regarded as a part of the reinforcement structure 108. According to various embodiments, the third region 214a may be configured to provide a reinforcement to support the chip, e.g. the third region 214a may include a copper layer 214a. According to various embodiments, the third region 214a or the copper layer 214a may also be regarded as a part of the reinforcement structure 108.

According to various embodiments, the glue structure 205 may include a first region 210b, e.g. a reinforcement structure 108, and a second region 212b, e.g. including a glue material. According to various embodiments, the first region 210b may have the same properties, the same functionalities and/or the same features as the reinforcement structure 108 as already described. According to various embodiments, the second region 212b, e.g. the adhesive material layer 212b, may include at least one of the following materials: glue, an adhesive, and a mold material. According to various embodiments, the second region 212b, e.g. the adhesive material layer 212b, may partially surround the first region 210b, e.g. the reinforcement structure 210b. The second region 212b, e.g. the adhesive material layer 212b may be formed by an under-fill process after the chip 104 may be arranged over the first region 210b, e.g. the reinforcement structure 210b.

According to various embodiments, the reinforcement structure 108 arranged between the chip 104 and the carrier 110 may further include a layer stack, not shown in figures, e.g. including a plurality of sublayers providing the stability for a reinforced region to protect the chip 104 or the increase the stability of the chip arrangement 100.

According to various embodiments, the antenna region including the carrier 110 and the antenna 106 may not be reinforced by the reinforcement structure 108, and therefore, the antenna 106 and the carrier 110 may be flexible, wherein the region of the carrier 110, which may include the chip 104, may be supported by the reinforcement structure 108 and therefore this region may have an increased stiffness.

The carrier 110 may have the shape of a quadratic plate, or the shape of a rectangular plate. The carrier may have substantially the shape of a quadratic plate, or substantially the shape of a rectangular plate. According to various embodiments, the carrier may be a quadratic plate or a rectangular plate having rounded corners.

Furthermore, the carrier 110 may include at least one contact pad, e.g. two contact pads, e.g. three contact pads, e.g. four contact pads, e.g. five contact pads, e.g. six contact pads, e.g. seven contact pads, e.g. eight contact pads, e.g. nine contact pads, e.g. ten contact pads, or even more the ten contact pads. According to various embodiments, the antenna 106 arranged on the carrier 110 may have an electrically conductive connection to the at least one contact pad. According to various embodiments, the antenna 106 may be electrically conductively coupled to the chip 104 via the at least one contact pad on the carrier 110. The at least one contact pad may be electrically conductively coupled to the chip 104 via the reinforcement structure 108 or the reinforcement structure elements 108a, 108c, as described before. The at least one contact pad may be electrically conductively coupled to the chip 104 via the additional layer 202 or the additional layer structure elements 202a, 202c, as described before.

According to various embodiments, the at least one contact pad may be arranged on the same side of the carrier, as the chip 104.

According to various embodiments, the carrier 110 may include or may consist of at least one material of the following group of materials: a plastic material, a flexible material, a polymer material, polyimide, a laminate material, or any other suitable material providing for example a flexible carrier.

According to various embodiments, the carrier 110 may have a thickness in the range from about 10 μm to about 200 μm, e.g. in the range from about 10 μm to about 100 μm, e.g. in the range from about 50 μm, e.g. a thickness larger than 50 μm or smaller than 50 μm. The carrier 110 may also include a substrate, a layer, a layer stack or a support structure.

The carrier 110 may include more than one type of material, e.g. a layer stack including a first layer of a first material and a second layer of a second material. According to various embodiments, the carrier 110 may include a metal layer or a metal alloy layer and a polymer layer. The carrier 110 may be a foil 100, e.g. a polymer foil or a plastic foil.

According to various embodiments, the chip 104 may include at least one of an integrated circuit, an electronic circuit, a memory chip, an RFID chip (radio-frequency identification chip), or any other type of chip, which may be subjected to a mechanical load during the use of the chip.

According to various embodiments, the chip 104 may include a silicon bulk layer, e.g. a silicon substrate or a silicon wafer, wherein the silicon bulk layer of the chip 104 may have a thickness in the range from about 10 μm to about 200 μm, e.g. in the range from about 20 μm to about 100 μm, e.g. in the range from about 30 μm to about 80 μm, e.g. in the range from about 50 μm, e.g. a thickness equal or less than 50 μm, e.g. 48 μm.

According to various embodiments, the chip 104 may include at least one metallization layer. According to various embodiments, the chip 104 may include at least one chip contact, wherein the at least one chip contact may provide the electrically conductive connection between the chip 104 and the at least one contact pad arranged on the carrier 110, as described above. According to various embodiments, the chip 104 may include at least one chip contact, wherein the at least one chip contact may provide the electrically conductive connection between the chip 104 and the antenna 106, e.g. via the at least one contact pad arranged on the carrier 110 as described above. According to various embodiments, the chip 104 may include at least one chip contact, wherein the at least one chip contact may provide the electrically conductive connection between the chip 104 and another component of the chip arrangement 100, e.g. with an additional contact pad structure arranged on the second side 110b of the carrier 110, e.g. via the at least one contact pad arranged on the carrier 110 as described above.

According to various embodiments, the carrier 110 may include at least one through hole or via, e.g. for electrically connecting the chip 104 with a further component of the chip arrangement, e.g. with an additional antenna or an additional contact pad structure arranged on the second side 110b of the carrier 110.

According to various embodiments, the reinforcement structure 108 may have a thickness in the range from about 1 μm to about 100 μm, e.g. in the range from about 10 μm to about 80 μm, e.g. in the range from about 30 μm to about 50 μm, e.g. in the range from about 50 μm, e.g. a thickness equal or less than 50 μm.

According to various embodiments, the solder structure 203 or the glue structure 205 may have a thickness in the range from about 1 μm to about 100 μm, e.g. in the range from about 10 μm to about 80 μm, e.g. in the range from about 30 μm to about 50 μm, e.g. in the range from about 50 μm, e.g. a thickness equal or less than 50 μm.

According to various embodiments, as described herein, a reinforcement structure may also include more than one reinforcement structures 108; in other words, the reinforcement structure 108 may include a plurality of reinforcement structure elements, proving in their entity a reinforced region to protect the chip 104 or to increase the stability of the chip arrangement.

According to various embodiments, the chip 104 may also include at least one chip cover layer, or the chip 104 may be covered with at least one chip cover layer, e.g. with a plastic material layer or with a polymer material layer. According to various embodiments, the chip 104 may include a polyimide layer on at least one side of the chip, e.g. having a thickness in the range from about 1 μm to about 50 μm, e.g. a thickness equal or less than 50 μm. According to various embodiments, the chip 104 may also be chip package, e.g. a thin chip package or a flexible chip package.

According to various embodiments, the solder structure 203 may include a solder layer 212a having a thickness in the range from about 0.5 μm to about 10 μm, e.g. in the range from about 1 μm to about 5 μm, e.g. a thickness in the range from about 2.5 μm.

According to various embodiments, the glue structure 205 may include an adhesive layer 212b having a thickness in the range from about 1 μm to about 50 μm, e.g. in the range from about 10 μm to about 20 μm, e.g. a thickness in the range from about 15 μm.

According to various embodiments, the following description may include modifications or extensions of the chip arrangement as described referring to FIG. 1A and FIG. 1B and referring to FIG. 2A to FIG. 2E, wherein the following illustrated modifications or extensions may be applied to any of the chip arrangements described herein.

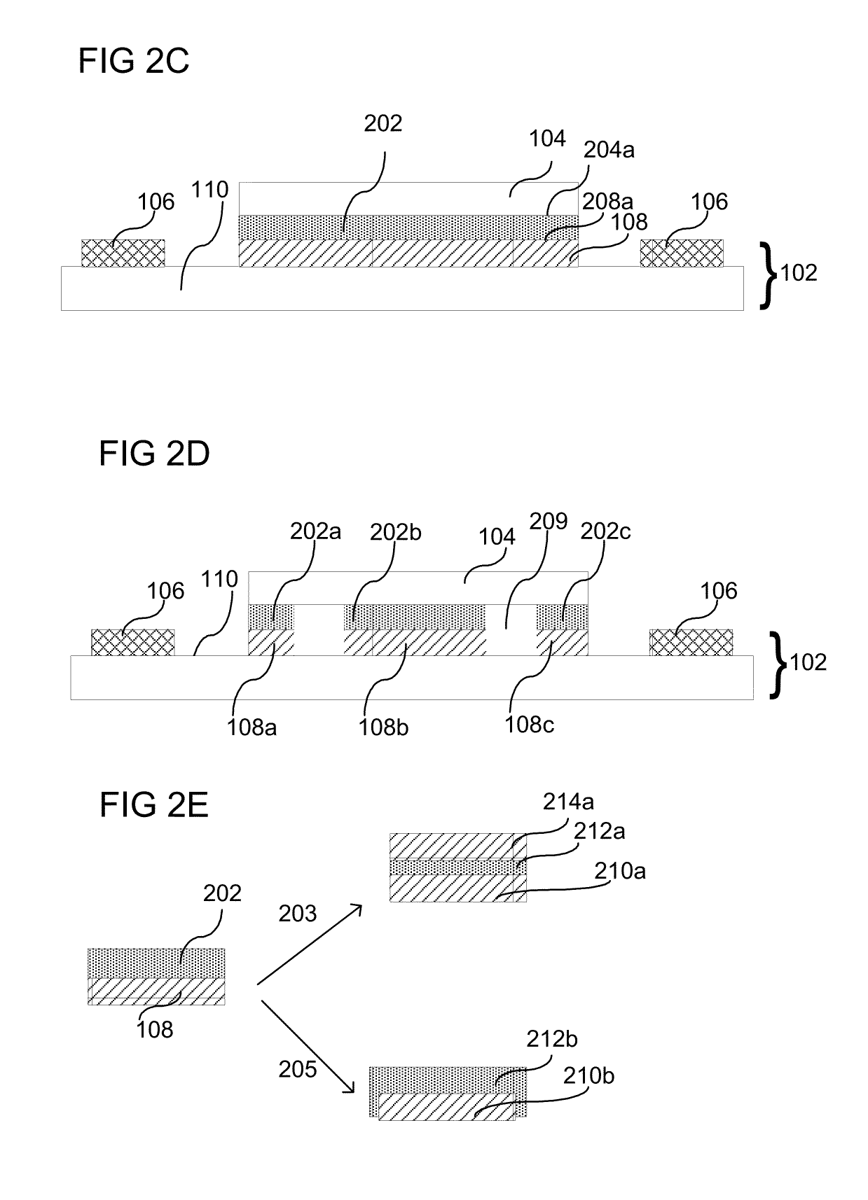

As shown in FIG. 3A, according to various embodiments, the chip may be attached to the carrier 110 via the reinforcement structure 108, wherein the antenna 106 is arranged on the same side as the chip 104 and the reinforcement structure 108, as already described herein. According to various embodiments, the chip arrangement 100, as shown in FIG. 3A, may further include an additional reinforcement structure 308, wherein the additional reinforcement structure 308 may be arranged at a second side 110b of the carrier 110, wherein the second side 110b may be opposite to a first side 110a of the carrier 100. According to various embodiments, the chip 104, the antenna 106 and the reinforcement structure 108 may be arranged on the first side 110a of the carrier 110, wherein the additional reinforcement structure 308 may be arranged at a second side 110b of the carrier 110. According to various embodiments, the chip 104, and the reinforcement structure 108 may be arranged on the first side 110a of the carrier 110, wherein the additional reinforcement structure 308 and the antenna 106 may be arranged on or over a second side 110b of the carrier 110 (not shown in figures). According to various embodiments, the additional reinforcement structure 308 may have the same functionalities as the reinforcement structure 108 described herein.

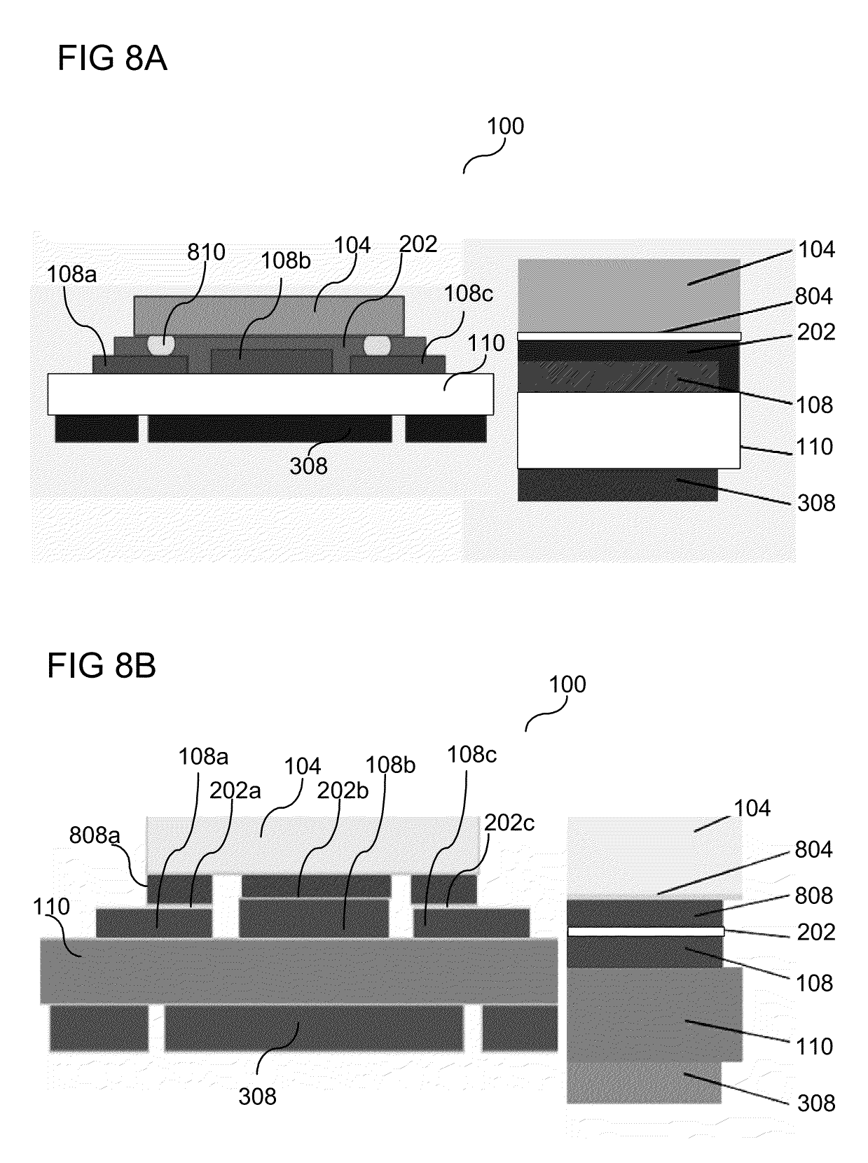

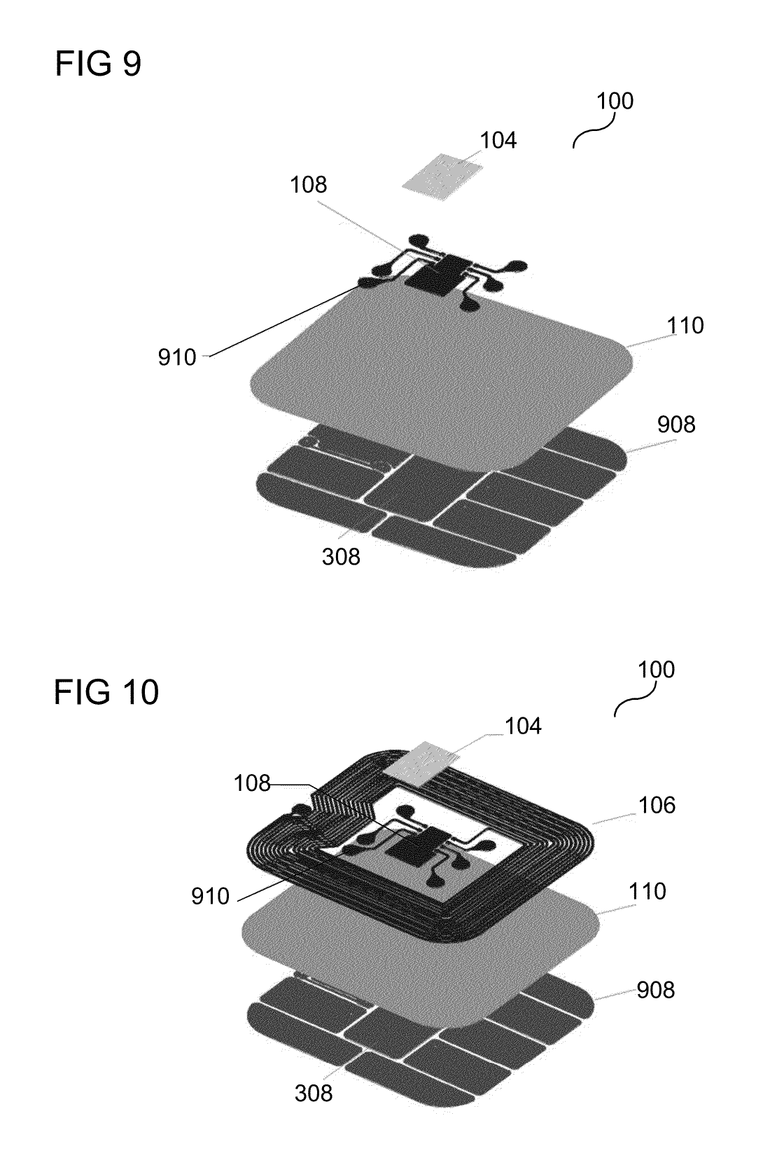

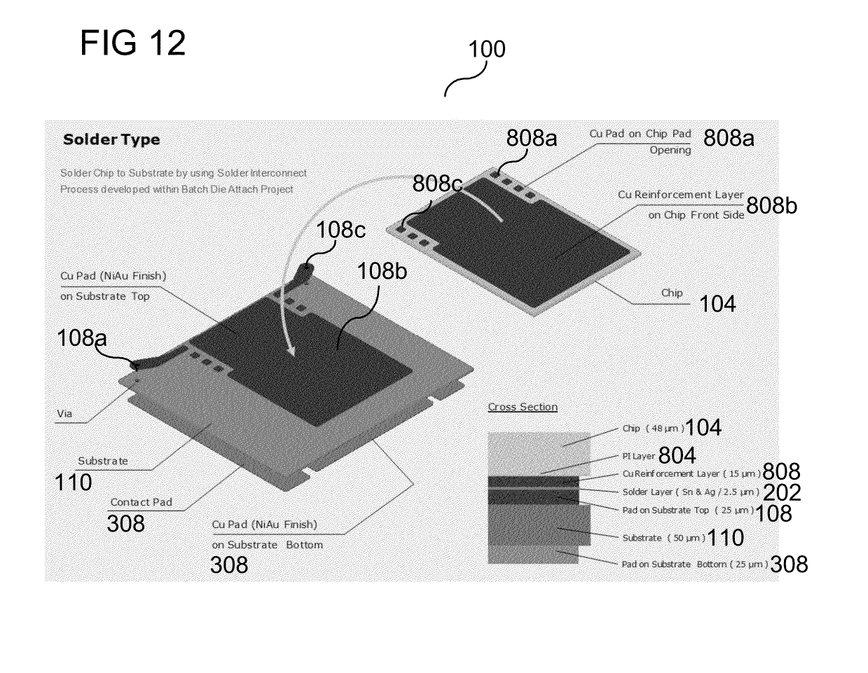

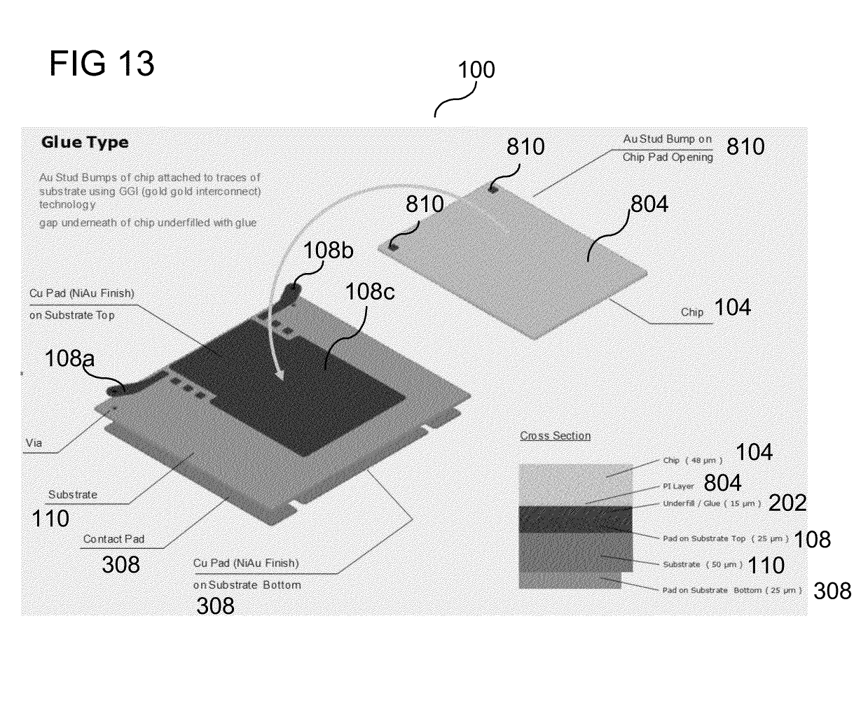

The additional reinforcement structure 308 may be at least part of a contact pad structure arranged on the second side 110b of the carrier 110. Moreover, the contact pad structure may be an ISO contact pad structure of a smart card (e.g. in accordance with ISO 7816), as shown schematically in FIG. 9, FIG. 10, FIG. 12, and FIG. 13.

The contact pad structure arranged on the second side 110b of the carrier 110 may be electrically conductively coupled to the chip 104, e.g. via through holes provided in the carrier 110. The contact pad structure arranged on the second side 110b of the carrier 110 may be electrically conductively coupled to the chip 104, e.g. via at least one of the through holes provided in the carrier 110, the contact pads arranged on the first side 110a of the carrier 110, the reinforcement structure 108, the additional layer 202, and the chip contact pads, as already described.

According to various embodiments, the contact pad structure arranged on the second side 110b of the carrier 110 may provide at least an electrical functionality, e.g. for electrically connecting the chip 104 to a peripheral device, and at least a mechanical functionality, e.g. as a reinforcement structure 308.

As shown in FIG. 3B, the chip may be attached to the carrier 110 via the reinforcement structure 108, wherein the antenna 106 is arranged on the same side, as the chip 104 and the reinforcement structure 108, as already described herein. According to various embodiments, the chip arrangement 100, as shown in FIG. 3A, may further include an additional antenna structure 306a arranged on the second side 110b of the carrier 110, opposite to the first side 110a of the carrier, wherein the chip may be attached on the first side 110a of the carrier 110. According to various embodiments, the additional antenna structure 306a may be electrically conductively coupled to the chip, e.g. via through holes, which may be provided in the carrier 110. The additional antenna structure 306a may be electrically conductively coupled to the chip, e.g. via at least one of the through holes provided in the carrier 110, the contact pads arranged on the first side 110a of the carrier 110, the reinforcement structure 108, the additional layer 202, and the chip contact pads, as already described.

According to various embodiments, the chip arrangement 100 as shown in FIG. 3A may provide a chip arrangement for a smart card, wherein the chip arrangement may provide a dual interface package, which may allow a data transfer between a peripheral device and the chip 104 using at least one of the additional contact pad structure 308 or the antenna structure 106.

According to various embodiments, the chip arrangement 100 as shown in FIG. 3B may provide a chip arrangement for a smart card, wherein the chip arrangement may provide a contact less interface package, which may allow a contact less data transfer between a peripheral device and the chip 104 using the antenna structure 106, 306.

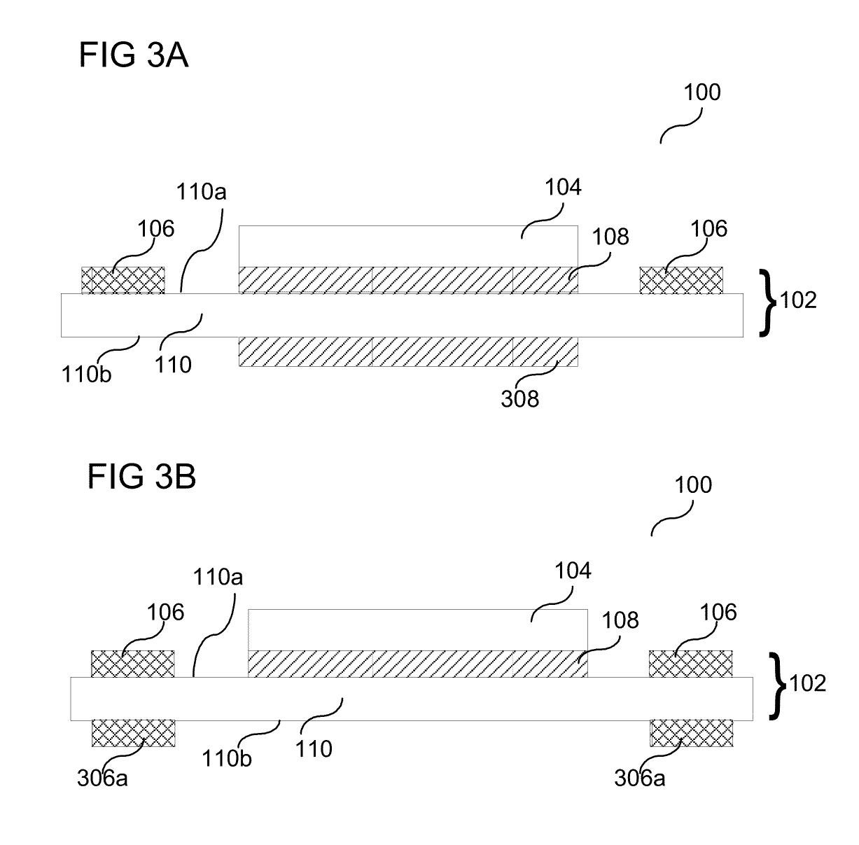

FIG. 4 shows a flow diagram of a method for manufacturing a chip arrangement, according to various embodiments, in analogy to the chip arrangement 100 as described herein. According to various embodiments, the method 400 for manufacturing a chip arrangement 100 may include, in 410, forming an antenna on a first side of a carrier, in 420, forming a reinforcement structure over the first side of the carrier, and, in 430, attaching a chip on the carrier such that the chip is protected by the reinforcement structure, wherein the chip is electrically connected to the antenna.

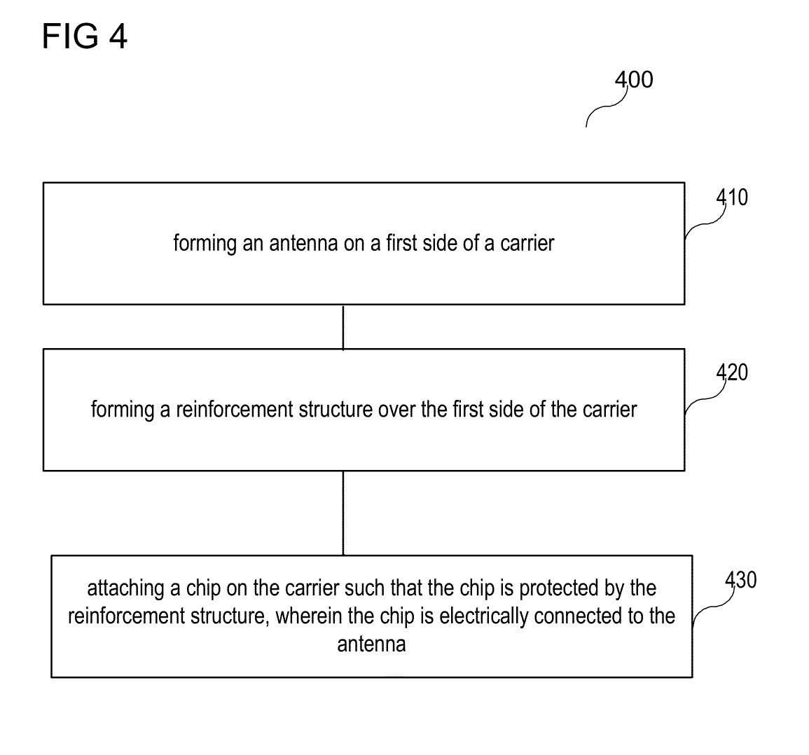

FIG. 5A shows a cross section of a carrier 110 after process 410 of method 400 has been carried out, according to various embodiments. According to various embodiments, an antenna 106 may be formed over a side of the carrier 110, as already described herein. According to various embodiments, forming the antenna 106 on a first side 110a of the carrier 110 may include applying at least one of a copper etch technology and an aluminum etch technology. According to various embodiments, forming the antenna 106 on a first side 110a of the carrier 110 may include applying a copper etch technology. According to various embodiments, the antenna 106 may be formed by covering the first side 110a of the carrier 110 at least partially with a copper layer, e.g. using a deposition process or a layering process (e.g. a physical vapor deposition or a chemical vapor deposition), and patterning the copper layer to provide an antenna 106 on the carrier 110. According to various embodiments, the patterning of the copper layer may include a chemical or physical etch process, e.g. wet etching or dry etching.

FIG. 5B shows a cross section of a carrier 110 after process 420 of method 400 has been carried out, according to various embodiments. According to various embodiments, a reinforcement structure 108 may be formed over the carrier 110, as already described herein. According to various embodiments, forming the reinforcement structure 108 on a first side 110a of a carrier 110 may include applying at least one of a copper etch technology and an aluminum etch technology. According to various embodiments, forming reinforcement structure 108 on a first side 110a of the carrier 110 may include applying a copper etch technology. According to various embodiments, the reinforcement structure 108 may be formed by covering the first side 110a of the carrier 110 at least partially with a copper layer, e.g. using a deposition process or a layering process (e.g. a physical vapor deposition or a chemical vapor deposition), and patterning the copper layer to provide a reinforcement structure 108 on the carrier 110. According to various embodiments, the patterning of the copper layer generating the reinforcement structure 108 may include a chemical or physical etch process, e.g. wet etching or dry etching.

According to various embodiments, the reinforcement structure 108 and the antenna 106 may be formed in the very same process, e.g. to provide a more efficient and cheaper manufacturing process. According to various embodiments, the reinforcement structure 108 may support the carrier 110 in a region 111, as shown in FIG. 5B. According to various embodiments, the flexibility of the carrier 110 may be reduced in the region 111 due to the reinforcement structure 108. According to various embodiments, the reinforcement structure 108 may also have another cross section than shown in FIG. 5B, e.g. as shown and described referring to FIG. 1B and FIG. 2D. Further, according to various embodiments, the reinforcement structure 108 may also include various types of materials (or more than one material) for example arranged in different regions of the reinforcement structure 108 or in different layers of the reinforcement structure 108.

According to various embodiments, the flexibility of the carrier 110 may be influenced or defined by the material of the carrier 110, e.g. including plastic material or polymer material, the thickness of the carrier 110, e.g. in the micrometer range, and the shape of the carrier 110, e.g. a foil-like shape or a sheet-like shape.

According to various embodiments, using a reinforcement structure 108 to support for example the chip 104 may allow to adapt the properties of the chip 104 with focus to provide for example a thin and cheap chip 104.

According to various embodiments, the carrier may have thickness equal or less than about 100 μm, e.g. in the range from about 10 μm to about 100 μm.

According to various embodiments, the reinforcement structure 108 may be formed over a side of the carrier 110, wherein the reinforcement structure 108 may be a copper layer having a thickness in the range from about 5 μm to about 100 μm, e.g. in the range from about 15 μm to about 60 μm, e.g. having a thickness equal or greater than about 20 μm.

FIG. 5C shows a cross section of the carrier 110 after process 430 of method 400 has been carried out, according to various embodiments. A chip 104 may be attached directly or indirectly to the carrier 110, as already described herein. According to various embodiments, the chip 104 may be attached directly to the carrier 110 over the reinforced region 111, e.g. on a second side 110b of the carrier 110 opposite to the reinforcement structure 108, which may be for example arranged on the first side 110a of the carrier 110 (not shown in figures). According to various embodiments, the chip 104 may be attached indirectly to the carrier 110 over the reinforced region 111, e.g. on the first side 110a of the carrier 110 over the reinforcement structure 108, as shown in FIG. 5C. The chip 104 may or may not extend over the reinforced region 111. According to various embodiments, the lateral extension (along the direction 101) of the chip 104 may be smaller than the lateral extension of the reinforced region 111 or the lateral extension of the reinforcement structure 108, as already described herein. The lateral extension of the chip 104 may be greater than the lateral extension of the reinforced region 111 or the lateral extension of the reinforcement structure 108, as already described herein. Furthermore, the lateral extension of the chip 104 may be equal to the lateral extension of the reinforced region 111 or the lateral extension of the reinforcement structure 108, as already described herein.

According to various embodiments, the chip 104 attached on the carrier 110 in process 430 may be a flexible chip. The flexibility of the chip 104 may be influenced or defined by the material of the chip 104, e.g. bulk silicon, the thickness of the chip 104, e.g. in the micrometer range, and the shape of the chip 104, e.g. a plate-like shape or a sheet-like shape. The chip may a thickness equal or less than 150 μm, e.g. a thickness equal or less than 100 μm, e.g. a thickness equal or less than 50 μm.

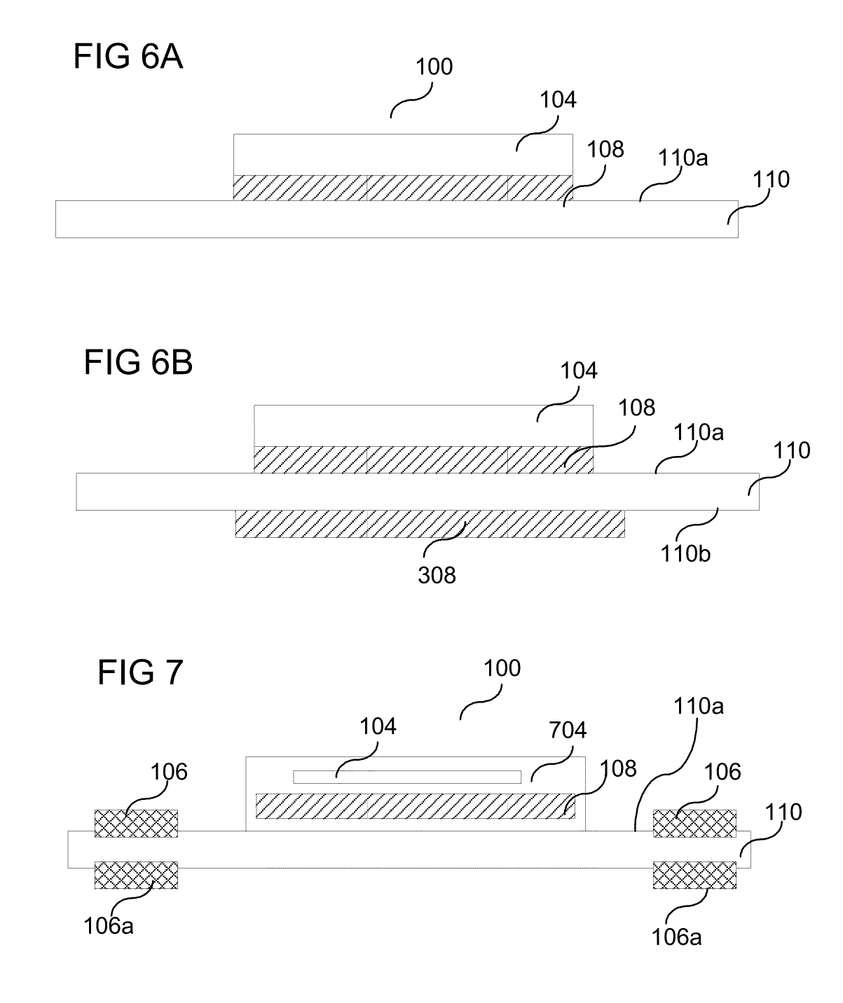

Attaching the chip 104 on the carrier 110 may include at least one of a soldering process and a gluing process, as described with reference to FIG. 8A, and FIG. 8B.

According to various embodiments, an electrically conductive connection between the chip 104 and the antenna 106 may be formed, e.g. via an electrically conductive connection between a chip contact pad and the antenna 106.

FIG. 5D shows a cross section of a carrier 110 after process 430 of method 400 has been carried out and after an additional reinforcement structure 308 is formed or attached on the second side 110b of the carrier 110, e.g. the side 110b of the carrier 110 facing away from the chip 104, according to various embodiments. The lateral extension (along the direction 101) of the additional reinforcement structure 308 may be smaller than the lateral extension of the reinforcement structure 108 or the lateral extension of chip 104. According to various embodiments, the lateral extension of the additional reinforcement structure 308 may be greater than the lateral extension of the reinforcement structure 108 or the lateral extension of the chip 104 herein. The lateral extension of the additional reinforcement structure 308 may be equal to the lateral extension of the reinforcement structure 108 and/or the lateral extension of the chip 104 herein.

As shown in FIG. 5D, according to various embodiments, the chip 104 may be supported by the reinforcement structure 108 and the additional reinforcement structure 308, or the stability of the chip arrangement 100 may be increased by the reinforcement structure 108 and the additional reinforcement structure 308. The chip 104 may be arranged in the reinforced region 111, wherein the reinforced region 111 may be more rigid or less flexible than the carrier 110 in the other regions, e.g. in regions below the antenna 106. The reinforced region 111 may be created by at least one reinforcement structure, e.g. one reinforcement structure 108, or two reinforcement structures 108, 308, or even more than two reinforcement structures 108a, 108b, 108c, 308.

At least one reinforcement structure of a plurality of reinforcement structures (e.g. the reinforcement structures 108a, 108b, 108c, 308) may have an additional functionality, e.g. to provide an electrical connection to the chip 104. The additional reinforcement structure 308 may be at least a part of a contact pad structure. In other words, one contact pad 308 of the contact pad structure may be configured to be a reinforcement structure 308 to increase the stability of the chip arrangement 100 and/or to protect the chip 104 by providing a reinforced region 111.

According to various embodiments, the reinforcement structure 108 arranged between the chip 104 and the carrier 110 may provide a stable electrical connection between the chip 104 and other components of the chip arrangement 100, e.g. between the chip 104 and the antenna 106, or between the chip 104 and the contact pad structure 308.

FIG. 5E shows a cross section of a carrier 110 after process 430 of method 400 has been carried out and after an additional antenna 106a is formed or attached on the carrier 110, e.g. on the second side 110b of the carrier 110 facing away from the chip 104. According to various embodiments, an electrical contact may be formed to provide an electrically conductive connection between the additional antenna 106a and the chip 104, e.g. via a through hole in the carrier 110 connecting the first side 110a of the carrier 110 with the second side 110b of the carrier 110.

According to various embodiments, the carrier may include a metallization, wherein the metallization may electrically connect at least two of the following components of the chip arrangement 100 with each other: the chip 104, the antenna 106, at least a part of the reinforcement structure 108, at least a part of the additional reinforcement structure 308, a through via in the carrier 110, a chip contact pad, a carrier contact pad arranged on the first side 110a of the carrier 110.

The chip arrangement 100 may include the chip 104, the antenna 106, the carrier 110, the reinforcement structure 108, an additional reinforcement structure 308, and an additional antenna 106a, in analogy to the chip arrangement 100 as described herein, but not shown in figures.

The additional reinforcement structure 308 or the contact pad structure 308 may provide an electrically conductive connection of the chip or the chip arrangement 100 to an external peripheral device (e.g. a card reader) to transfer data to the chip 104 and from the chip 104.

The antenna 106 and or the additional antenna 106a may provide an inductively coupled electrical connection of the chip or the chip arrangement 100 to an external peripheral device (e.g. to a card reader) to transfer data to the chip 104 and from the chip 104.

Since the chip arrangement 100, as shown herein, may be flexible despite being reinforced in at least on region (e.g. in reinforced region 111) the carrier 110 may be processed in a reel to reel system. According to various embodiments, processing the chip arrangement 100 in a reel to reel system may allow an efficient and cheap manufacturing process, wherein for example a plurality of chip arrangements 100 may be processed on a cheap flexible carrier 110 in a reel to reel process.

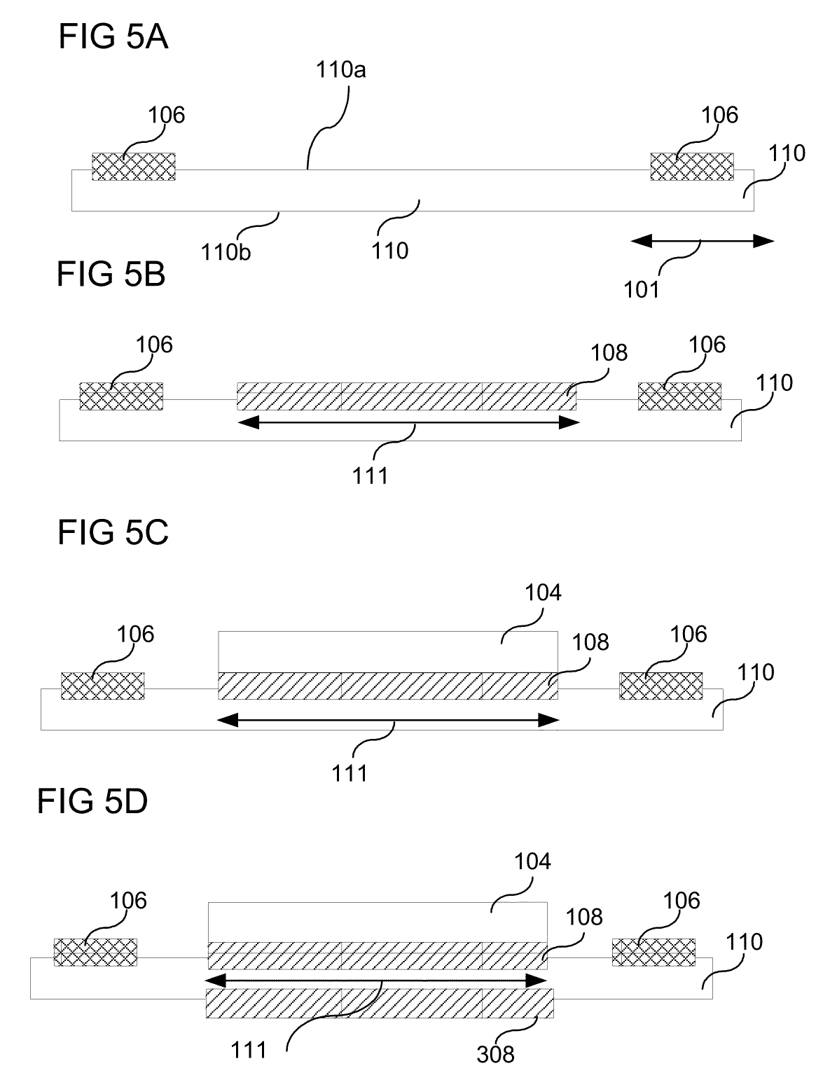

As shown in FIG. 6A and FIG. 6B, the chip arrangement 100 may include the chip 104 and the reinforcement structure 108 arranged on the carrier 110. According to various embodiments, the electrically conductive connection between the chip and a peripheral device may be provided by the contact pad structure 308, e.g. arranged on the second side 110b of the carrier 110. The chip arrangement 100 may not have an antenna to provide a contactless data transfer to the chip.

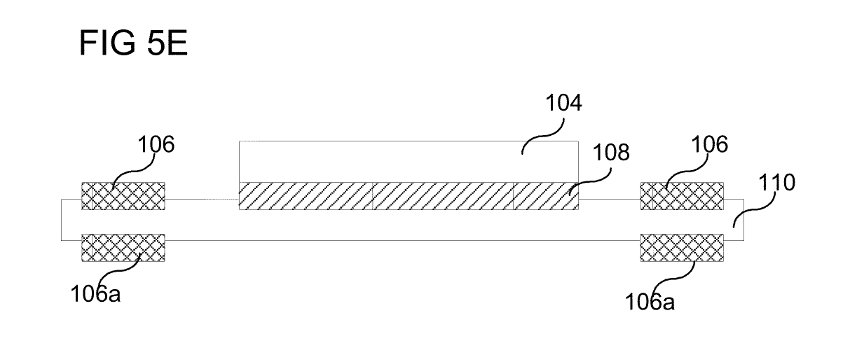

FIG. 7 shows a chip arrangement 100 including an antenna 106 and an additional antenna 106a enabling a contactless data transfer from the chip 104 and/or to the chip 104. The chip 104 may be provided in a chip package 704, wherein the chip package 704 may include a reinforcement structure 108. The chip package 704 may be attached or may be arranged on the carrier 110, as shown in FIG. 7.

According to various embodiments, the reinforcement structure 108 included in the chip package 704 may at least partially provide a metallization for the chip 104, which means that the reinforcement structure 108 may provide for example an electrically conductive connection between the chip 104 and the antenna 106, 106a.

According to various embodiments, since the reinforcement structure 108 or the reinforcement structures 108a, 108c, 308 may serve to provide an electrically conductive connection to the chip, the stability of the chip arrangement 100 may be increased, since the electrical functionality may be obtained after a mechanical load has been applied to the chip arrangement 100.

FIG. 8A shows a cross section of a chip arrangement 100 and a detailed view of the cross section of the chip arrangement 100 (on the right side), according to various embodiments. According to various embodiments, FIG. 8A illustrates the chip arrangement 100, wherein the chip 104 is disposed or arranged over the carrier 110 and the reinforcement structure 108 (using a glue structure 205), in analogy to the chip arrangement 100 as already described before. The electrical connection between the chip 104 and the reinforcement structure 108 may be provided by a bump 810, e.g. providing the electrically conductive connection between the chip 104 and the reinforcement structure 108a. The bump 810 may include at least one of the following materials: a metal, a metal alloy, an electrically conductive material, a solder material, tin, zinc, lead, indium, carbon, gold, silver, and the like. According to various embodiments, the bump 810 may be arranged over or may be a part of a chip contact. According to various embodiments, the chip 104 may be arranged over the reinforcement structure 108a, 108b, 108c such that the reinforcement structure elements 108a, 108c may provide an electrically conductive connection between the chip 104 and another component of the chip arrangement 100, e.g. between the chip 104 and the contact pad structure 308 or between the chip 104 and the antenna 106, as described herein. According to various embodiments, the carrier 110, as shown in FIG. 8A, may extend further than it is shown in the figure to provide a support for an antenna. The space between the chip 104 and the reinforcement structure 108 may be filled with a material or material layer 202, e.g. with a glue or an adhesive material. Since electrical connection between the chip and the reinforcement structure 108 may be provided by the bumps 810, the material 202 may be an electrically insulating material. According to various embodiments, an insulating material 202 may be filled between the chip 104 and the reinforcement structure 108, in a so-called under-fill process. The glue 202 (or the additional material layer 202) may also provide reinforcement, for example to reinforce the carrier 110 in a region below the chip 104 or to provide stability for the chip arrangement 100. The mechanical properties of the glue 202 (or the additional material layer 202) may be selected to provide a stable chip arrangement 100. According to various embodiments, the glue 202 or the additional material layer 202 may be flexible or rigid.

The contact pad structure 308 may be configured to act at least partially as a reinforcement structure 308. According to various embodiments, as already described, the chip 104 may be covered with an additional cover layer 804, e.g. a polyimide layer, e.g. polymer layer, wherein the additional cover layer 804 may be flexible. The additional cover layer 804 may have a thickness in the range from about 1 μm to about 100 μm, e.g. in the range from about 1 μm to about 50 μm, e.g. a thickness equal or less than 50 μm or less than 10 μm.

According to various embodiments, the additional cover layer 804 may be arranged between the chip 104 and the carrier 110, e.g. between the chip 104 and the reinforcement structure 108, e.g. between the chip 104 and the additional layer 202. Further, the chip 104 may be covered with two cover layers 804 (not shown in figures), wherein one cover layer 804 may be arranged on a first side of the chip 104 such that the cover layer 804 may be arranged between the chip 104 and the carrier 110, as already described, and another cover layer may be arranged on a second side of the chip 104, opposite to the first side of the chip (e.g. the second side may face away from the carrier).

FIG. 8B shows a cross section of a chip arrangement 100 and a detailed view of the cross section of the chip arrangement 100 (on the right side), according to various embodiments. According to various embodiments, FIG. 8B illustrates the chip arrangement 100, wherein the chip 104 is disposed or arranged over the carrier 110 and the reinforcement structure 108 (e.g. using a solder structure 203), in analogy to the chip arrangement 100 as already described before. According to various embodiments, the electrical connection between the chip 104 and the reinforcement structure 108, 108a, 108b, 108c may be provided by the solder layers 202a, 202b, 202c covering the reinforcement structure elements 108a, 108b, 108c and by the reinforcement structure 808 or material layer 808 arranged between the solder layers 202a, 202b, 202c and the chip 104. The electrically conductive connection between the chip 104 and the reinforcement structure 108a may be provided by the solder layer 202a and the material layer 808a, as shown in FIG. 8B. According to various embodiments, the solder layer 202 or the solder layers 202a, 202b, 202c may include at least one of the following materials: a metal, a metal alloy, an electrically conductive material, a solder material, tin, zinc, lead, indium, carbon, gold, silver, and the like. According to various embodiments, the chip 104 may be arranged over the reinforcement structure 108a, 108b, 108c, such that the reinforcement structure elements 108a, 108c may provide an electrically conductive connection between the chip 104 and another component of the chip arrangement 100, e.g. between the chip 104 and the contact pad structure 308 or between the chip 104 and the antenna 106, as described herein. The carrier 110, as shown in FIG. 8B, may extend further than it is shown in the figure to provide a support for an antenna. The space between the reinforcement structure 108a and the reinforcement structure 108b or between the reinforcement structure 108c and the reinforcement structure may be any empty space (including no material). According to various embodiments, since electrical connection between the chip and the reinforcement structure 108 may be provided by the solder layers 202a and 202c, the solder material forming the solder layers may be an electrically conductive material. The solder layer 202 (or the additional material layer 202) may also provide reinforcement, for example to reinforce the carrier 110 in a region below the chip 104 or to provide stability for the chip arrangement 100.

According to various embodiments, the contact pad structure 308 may be configured at least partially as reinforcement structure 308. As already described, the chip may be covered with at least one additional cover layer 804, e.g. a polyimide layer, e.g. polymer layer. The additional cover layer 804 may be arranged between the chip 104 and the carrier 110, e.g. between the chip 104 and the reinforcement structure 108, e.g. between the chip 104 and the additional layer 202.

According to various embodiments, FIG. 9 shows schematically an illustration of the chip arrangement 100, as described herein, wherein the illustrated distances between the components of the chip arrangement 100 is enlarged so that the components of the chip arrangement 100 are illustrated separated from each other for a better view. According to various embodiments, the reinforcement structure 108 may be arranged over a carrier 110, e.g. on top of the carrier 110. According to various embodiments, electrical contacts 910 or a metallization structure 910 may be arranged in the same layer as the reinforcement structure 108. According to various embodiments, the metallization structure 910 may provide at least one electrical contact on the carrier, e.g. on the top side of the carrier, for electrically connecting the contact pad structure 908, including the reinforcement structure 308, to the chip 104. According to various embodiments, the reinforcement structure 308 may also be part of the contact structure 308; in other words, the contact pad structure 308, which may be the contact pad structure 908 of a smart card (or of a chip arrangement 100 used in a smart card), may be at least partially configured as a reinforcement structure 308 at the same time.

According to various embodiments, FIG. 10 shows a schematic illustration of a chip arrangement 100, as described herein, in analogy to FIG. 9. The chip arrangement 100 may further include an antenna 106. According to various embodiments, the antenna 106 may surround the reinforcement structure 108 and the metallization structure 910. The reinforcement structure 108, the antenna 106 and the electrical contacts 910 (e.g. metallization structure 910 on the carrier 110) may be formed within the very same process, e.g. using a copper-etch technology. According to various embodiments, electrical contacts 910 and the antenna 106 may be arranged in the same layer as the reinforcement structure 108. The metallization structure 910 may provide electrical contacts on the carrier, e.g. on the top side of the carrier, for electrically connecting the contact pad structure 908, including the reinforcement structure 308, to the chip 104. The reinforcement structure 308 may also be part of the contact structure 308; in other words, the contact pad structure 308, which may be the contact pad structure 908 of a chip card (or of a chip arrangement 100 used in a chip card), may be at least partially configured as a reinforcement structure 308 at the same time.

According to various embodiments, the chip arrangement 100 as described herein may be a part of a smart card or a chip card, e.g. including an antenna 106 for contact less data transfer or including a contact pad 308, 908 for the data transfer, or e.g. a dual interface chip card including a contact pad 308, 908 and an antenna 106.

According to various embodiments, the chip arrangement 100 as described herein may provide an enhanced mechanical and electrical stability, since the chip 104 may be a flexible chip, and also the carrier 110 may be flexible, and the reinforcement structure 108 supporting the chip 104. The use of flexible components and reinforcement structures may provide an optimal balance between flexibility, such that the chip arrangement 100 or the chip 104 may not break or suffer damage from bending or mechanical load, and stiffness, such that the electrical contacts or the metallization of the chip arrangement 100 or of the chip 104 may not suffer damage from a mechanical load.

A mechanical load may be a pressure, a force, a force impact, a bending, torsion, a shearing, a tension, a stress, a shear stress, a tensile stress, or a deformation in general inducing a strain into the chip arrangement 100.

A first part of the chip arrangement 100 may be substantially rigid, e.g. the reinforced region 111, wherein a second part of the chip arrangement 100 may be substantially flexible, e.g. the carrier 110 in the regions being not reinforced by a reinforcement structure 108, 308.

According to various embodiments, the reinforcement structure 108 may be a layer or a layer stack, or may be provided in another way, as for example as a reinforcement grid, or as a plurality of reinforcement structures, e.g. a plurality of reinforcement pillars, fins, and the like.

According to various embodiments, the chip 104 may have a thickness in the range from about 10 μm to about 200 μm, e.g. in the range from about 20 μm to about 100 μm, e.g. in the range from about 30 μm to about 80 μm, e.g. in the range from about 50 μm, e.g. a thickness equal or less than 50 μm, e.g. 48 μm.

According to various embodiments, the chip arrangement 100 may have an optimal arrangement of the components (e.g. carrier 110, reinforcement structure 108, 308, chip 104) to provide an optimal stability to withstand a point pressure.

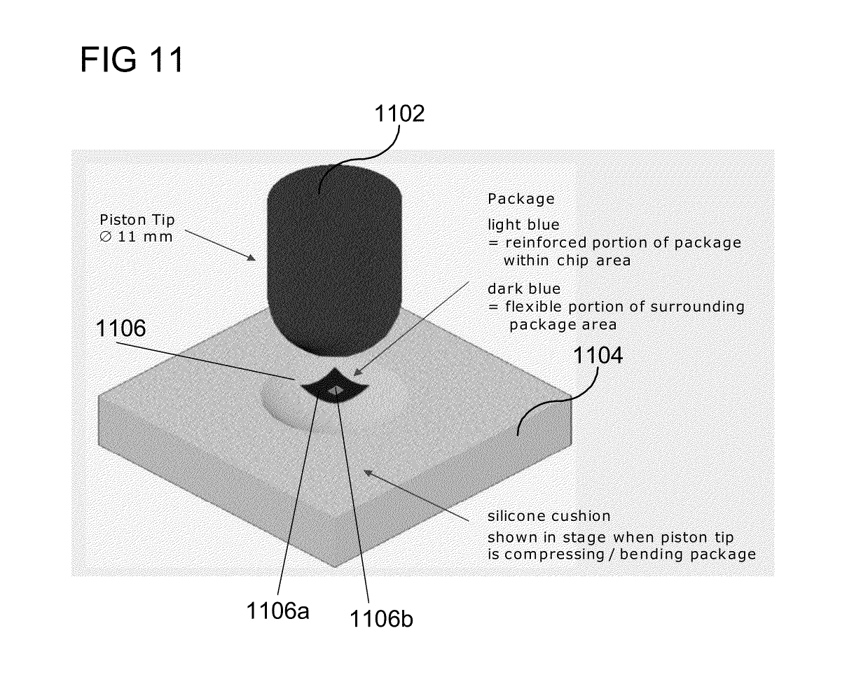

As shown in FIG. 11, a so called point pressure test may be carried out for testing the stability of a chip or a chip arrangement, e.g. a chip arrangement including a chip package. Therefore, a piston tip 1102, e.g. having a spherical tip with a diameter of about 11 mm, is pressed into a silicon cushion 1104, wherein the device 1106 to be tested, e.g. the package or the chip arrangement, is positioned between the piston tip 1102 and the silicon cushion 1104. According to various embodiments, the point pressure test may be a reference test for robustness or mechanical stability of an electronic device or chip or chip package. According to various embodiments, the point pressure test results of an electronic device may correlate to the returns quantity of an electronic device in trade, or e.g. to the durability. FIG. 11 shows schematically the chip arrangement 1106 in the compressed state, wherein the chip arrangement is deformed. According to various embodiments, the chip arrangement, as shown, may include a flexible portion 1106a of surrounding package area and a reinforced portion 1106b of the package within the chip area.

According to various embodiments, in this point pressure test arrangement the package or the chip arrangement may be subjected rather to pressure than to a bending load. According to various embodiments, flexible chip arrangements may have excellent package breakage strength, since thin silicon substrates, e.g. having a thickness of about 50 μm, may for example rather bend than break. In contrast, the chip arrangement or the chip may further include metallization layers and dielectric layers, which may be affect, e.g. may crack, if a tension is applied. However, the breakage of the metallization layers and/or dielectric layers may not be detected in a point pressure test, since the chip may not brake, but despite lose the functionality.

The chip arrangement as described herein may have a package breakage strength in the classical point pressure test and may further be resistant to a tension, since the electrical functionality may remain, e.g. while the chip arrangement is bent.

FIG. 12 shows a schematic perspective view of a chip arrangement 100 and a detailed view of the cross section of the chip arrangement 100 (in the lower right side), in analogy to the chip arrangement 100 as shown and described referring for example to FIG. 8B, according to various embodiments. FIG. 12 illustrates the chip arrangement 100, wherein the chip 104 is actually disposed or arranged over the carrier 110 and the reinforcement structure 108 (using a solder structure), in analogy to the chip arrangement 100 as already described before.

According to various embodiments, the electrical connection between the chip 104 and the reinforcement structure 108, 108a, 108b, 108c may be provided by the solder layers 202a, 202b, 202c covering the reinforcement structure elements 108a, 108b, 108c and by the reinforcement structure 808 or material layer 808 arranged between the solder layers 202a, 202b, 202c and the chip 104 as illustrated in detail in FIG. 8B. According to various embodiments, the chip 104 may be arranged over the reinforcement structure 108a, 108b, 108c, such that the reinforcement structure elements 108a, 108c may provide an electrically conductive connection between the chip 104 and another component of the chip arrangement 100, e.g. between the chip 104 and the contact pad structure 308 or between the chip 104 and the antenna 106, as described before. The carrier 110, as shown in FIG. 12, may or may not extend further than it is shown in the figure, e.g. to provide a support for an antenna. The space between the reinforcement structure 108a and the reinforcement structure 108b or between the reinforcement structure 108c and the reinforcement structure may be any empty space. Since electrical connections between the chip and the reinforcement structure 108 may be provided by the solder layers 202a and 202c, the solder material forming the solder layers may be an electrically conductive material. The solder layer 202 (or the additional material layer 202) may also provide reinforcement, for example to reinforce the carrier 110 in a region below the chip 104 or to provide stability for the chip arrangement 100.

According to various embodiments, the contact pad structure 308 may be configured at least partially as reinforcement structure 308. According to various embodiments, as already described, the chip may be covered with at least one additional cover layer 804, e.g. a polyimide layer, e.g. polymer layer. The additional cover layer 804 may be arranged between the chip 104 a copper layer 808.

FIG. 13 shows a schematic perspective view of a chip arrangement 100 and a detailed view of the cross section of the chip arrangement 100 (in the lower right side), in analogy to the chip arrangement 100 as shown and described referring for example to FIG. 8A, according to various embodiments. FIG. 13 illustrates the chip arrangement 100, wherein the chip 104 is actually disposed or arranged over the carrier 110 and the reinforcement structure 108 (using a glue structure), in analogy to the chip arrangement 100 as already described before. According to various embodiments, the electrical connection between the chip 104 and the reinforcement structure elements 108a, 108c may be provided by two bumps 810, e.g. providing the electrically conductive connection between the chip 104 and the reinforcement structure 108a, 108c. The bumps 810 may include at least one of the following materials: a metal, a metal alloy, an electrically conductive material, a solder material, tin, zinc, lead, indium, carbon, gold, silver, and the like. The chip 104 may be arranged over the reinforcement structure 108 (or e.g. over the reinforcement structure elements 108a, 108b, 108c) such that the reinforcement structure elements 108a, 108c may provide an electrically conductive connection between the chip 104 and another component of the chip arrangement 100, e.g. between the chip 104 and the contact pad structure 308 or between the chip 104 and the antenna 106, as described before. The space between the chip 104 and the reinforcement structure 108 may be filled with a material or material layer 202, e.g. with a glue or an adhesive material. Since electrical connection between the chip and the reinforcement structure 108 may be provided by the bumps 810, the material 202 may be an electrically insulating material. An insulating material 202 may be filled between the chip 104 and the reinforcement structure 108, in a so-called under-fill process. According to various embodiments, the glue 202 (or the additional material layer 202) may also provide reinforcement, for example to reinforce the carrier 110 in a region below the chip 104 or to provide stability for the chip arrangement 100. The mechanical properties of the glue 202 (or the additional material layer 202) may be selected to provide a stable chip arrangement 100. The glue 202 or the additional material layer 202 may be flexible or rigid.

According to various embodiments, FIG. 12 and FIG. 13 may also illustrate a part of the method for manufacturing a chip arrangement, as described herein, and in analogy to the method for manufacturing a chip arrangement, as already described.

According to various embodiments, the contact pad structure 308 may be configured to act at least partially as a reinforcement structure 308 or an additional reinforcement structure. As already described, the chip 104 may be covered with an additional cover layer 804, e.g. a polyimide layer, e.g. polymer layer, wherein the additional cover layer 804 may be flexible. The additional cover layer 804 may be arranged between the chip 104 and the glue 202.

According to various embodiments, the chip arrangement 100 may include chip card contacts 308, e.g. ISO contacts. According to various embodiments, the chip arrangement 100 may include chip card contacts 308, e.g. ISO contacts, and an antenna.

According to various embodiments, the chip arrangement 100, or a chip package, or a chip package arrangement similar to chip arrangement 102, may have an adequate stiffness in a region of the chip 104, e.g. in the reinforced region, to protect the active structures of the chip 104, wherein, at the same time, the remaining regions of the chip arrangement 100 are configured flexible. According to various embodiments, therefore, the chip arrangement 100 as described herein may have an enlarged lifetime during use.

According to various embodiments, a chip arrangement may include a chip; an antenna structure disposed over a first side of the chip, the antenna structure may include: an antenna being electrically conductively coupled to the chip; and a reinforcement structure, which may optionally be coupled to the antenna structure. The reinforcement structure may support the chip to increase the stability of the chip arrangement.

The antenna and the reinforcement structure may be formed in the very same layer. The antenna and the reinforcement structure may be formed on the same side of a carrier.

According to various embodiments, the reinforcement structure may be formed from or may include at least one of a metal and a metal alloy.

According to various embodiments, the antenna and the reinforcement structure may be formed from or may include the same material. According to various embodiments, the antenna and the reinforcement structure may be formed from or may include the same material.

According to various embodiments, the antenna structure may further include a carrier, wherein the antenna and the reinforcement structure may be arranged on the same side of the carrier facing the chip.

According to various embodiments, at least one of a solder layer and a glue layer may be arranged between the chip and the carrier for attaching the chip on the carrier. According to various embodiments, at least one of a solder layer and a glue layer may be formed between the chip and the carrier for attaching the chip on the carrier.

According to various embodiments, the antenna structure may further include an additional antenna, wherein the additional antenna may be arranged on the opposite side of the carrier facing away from the chip.

According to various embodiments, an electrical contact structure may be arranged on a side of the carrier facing the chip; and a contact pad structure may be arranged on the side of the carrier facing away from the chip, wherein the electrical contact structure electrically connects the chip to the contact pad structure. According to various embodiments, an electrical contact structure may be arranged on a side of the carrier facing the chip; and a contact pad structure may be arranged on the side of the carrier facing away from the chip, wherein the electrical contact structure may allow to electrically connect the chip to the contact pad structure and wherein the contact pad structure may allow to electrically connect and/or transfer data to an external device, e.g. to a card reader or to a chip card terminal

According to various embodiments, at least a part of the contact pad structure may be configured to be an additional reinforcement structure being arranged to increase the stability of the chip arrangement. According to various embodiments, at least a part of the contact pad structure may be configured to be an additional reinforcement structure to reinforce a region of the carrier.

According to various embodiments, the chip may further include at least one chip cover layer covering at least one side of the chip. According to various embodiments, the chip may further include at least one chip cover layer covering two opposite sides of the chip.

According to various embodiments, the chip cover layer may include at least one of a plastic material and a polymer.

According to various embodiments, wherein the reinforcement structure may have a thickness in the range from about 5 μm to about 100 μm or in the range from about 20 μm to about 50 μm.

According to various embodiments, the chip may have a thickness equal or less than 100 μm.

According to various embodiments, the chip may have a thickness equal or less than 50 μm.

According to various embodiments, a method for manufacturing a chip arrangement may include: forming an antenna on a first side of a carrier; forming a reinforcement structure over the first side of the carrier, attaching a chip on the carrier such that the chip is protected by the reinforcement structure, wherein the chip is electrically connected to the antenna.

According to various embodiments, forming the antenna on a first side of a carrier may include applying at least one of a copper etch technology and an aluminum etch technology.

According to various embodiments, forming the antenna on a first side of a carrier may include forming an antenna over the carrier, wherein the carrier may have a thickness equal or less than about 100 μm. According to various embodiments, the carrier may have a sufficient small thickness to be a flexible carrier.

According to various embodiments, forming the reinforcement structure over the carrier may include forming a copper layer having a thickness equal or greater than about 20 μm. According to various embodiments, the reinforcement structure may support or protect the chip from being damaged by an appropriate mechanical load (typically occurring during the use of the chip arrangement).

According to various embodiments, attaching the chip on the antenna structure may include attaching a chip having a thickness equal or less than 50 μm.

According to various embodiments, attaching the chip on the carrier may include at least one of a soldering process and a gluing process.

According to various embodiments, attaching the chip on the carrier may further include forming an electrically conductive connection between the chip and the antenna.

According to various embodiments, forming the antenna structure and forming the reinforcement structure may be carried out in the very same process.

According to various embodiments, an additional reinforcement structure may be formed such that the additional reinforcement may be arranged on the side of the carrier facing away from the chip.

According to various embodiments, forming an additional reinforcement structure may further include forming a contact pad structure, wherein the additional reinforcement structure may be at least a part of the contact pad structure, wherein the contact pad structure may be electrically connected to the chip.

According to various embodiments, an additional antenna may be formed, such that the additional antenna may be arranged on the side of the carrier opposite to the first side of the carrier.

According to various embodiments, the carrier may be processed using a reel to reel system.

According to various embodiments, a chip arrangement may include a flexible carrier; at least one reinforcement structure arranged on the carrier; and a flexible chip arranged on the carrier supported by the reinforcement structure.

According to various embodiments, a first reinforcement structure may be arranged on a first side of the carrier and a second reinforcement structure may be arranged on a second side of the carrier, opposite to the first side of the carrier.

According to various embodiments, the additional reinforcement structure may be at least part of a contact pad structure, wherein the contact pad structure is electrically connected to the chip. According to various embodiments, the additional reinforcement structure may be at least part of a contact pad structure, wherein the contact pad structure is electrically connected to the chip and wherein the contact pad structure the may allow an electrical connection between the chip and an external device (e.g. to transfer data from the chip (readout) and to the chip (writing)).

According to various embodiments, a chip arrangement may include: a chip package including a flexible chip and at least one reinforcement structure; and a flexible carrier being attached to the chip package; an antenna structure being arranged on the flexible carrier, wherein the antenna structure may be electrically conductively connected to the chip.

While the invention has been particularly shown and described with reference to specific embodiments, it should be understood by those skilled in the art that various changes in form and detail may be made therein without departing from the spirit and scope of the invention as defined by the appended claims. The scope of the invention is thus indicated by the appended claims and all changes which come within the meaning and range of equivalency of the claims are therefore intended to be embraced.

1. A chip arrangement, comprising:
a chip;
an antenna structure disposed over a first side of the chip, the antenna structure comprising:
a carrier to which the chip is attached;
an antenna being electrically conductively coupled to the chip; and
a reinforcement structure supporting the chip to increase the stiffness of the chip arrangement.

2. The chip arrangement of claim 1, wherein the antenna and the reinforcement structure are formed in the same layer.

3. The chip arrangement of claim 1, wherein the reinforcement structure is formed from at least one of a metal and a metal alloy.

4. The chip arrangement of claim 1, wherein the antenna and the reinforcement structure are formed from the same material.

5. The chip arrangement of claim 1, wherein the antenna and the reinforcement structure are arranged on the same side of the carrier facing the chip.

6. The chip arrangement of claim 5, wherein at least one of a solder layer and a glue layer is arranged between the chip and the carrier.

7. The chip arrangement of claim 5, wherein the antenna structure further comprises an additional antenna, wherein the additional antenna is arranged on the opposite side of the carrier facing away from the chip.

8. The chip arrangement of claim 5, further comprising:
an electrical contact structure arranged on the side of the carrier facing the chip; and
a contact pad structure arranged on the side of the carrier facing away from the chip, wherein the electrical contact structure electrically connects the chip to the contact pad structure.

9. The chip arrangement of claim 9, wherein at least a part of the contact pad structure is configured as an additional reinforcement structure being arranged to increase the stiffness of the chip arrangement.

10. The chip arrangement of claim 1, wherein the chip further comprises at least one chip cover layer covering at least one side of the chip.

11. The chip arrangement of claim 10, wherein the chip cover layer comprises at least one of a plastic material and a polymer.

12. The chip arrangement of claim 1, wherein the reinforcement structure has a thickness in the range from about 5 μm to about 100 μm.

13. The chip arrangement of claim 1, wherein the chip has a thickness equal or less than about 100 μm.

14. A method for manufacturing a chip arrangement, the method comprising:
forming an antenna on a first side of a carrier;
forming a reinforcement structure over the first side of the carrier;
attaching a chip on the carrier such that the chip is protected by the reinforcement structure, wherein the chip is electrically connected to the antenna; and
wherein the reinforcement structure increases the stiffness of the chip arrangement.

15. The method of claim 14, wherein forming the antenna on a first side of a carrier comprises applying at least one of a copper etch technology and an aluminum etch technology.

16. The method according to claim 14, wherein forming the antenna on a first side of a carrier comprises forming an antenna over the carrier, wherein the carrier has a thickness equal or less than about 200 μm.

17. The method of claim 14, wherein forming the reinforcement structure over the carrier comprises forming a copper layer having a thickness equal or greater than about 20 μm.

18. The method of claim 14, wherein attaching the chip on the carrier comprises attaching a chip having a thickness equal or less than about 100 μm.

19. The method of claim 14, wherein attaching the chip on the carrier comprises at least one of a soldering process and a gluing process.

20. The method of claim 14, wherein forming the antenna and forming the reinforcement structure are carried out in the very same process.

21. The method of claim 14, further comprising:
forming an additional reinforcement structure being arranged on the side of the carrier facing away from the chip.

22. The method of claim 21, wherein forming an additional reinforcement structure further comprises forming a contact pad structure, wherein the additional reinforcement structure is at least a part of the contact pad structure, wherein the contact pad structure is electrically connected to the chip.

23. The method of claim 14, wherein the carrier is processed in a reel to reel system.

24. A chip arrangement, comprising:
a flexible carrier;
at least one reinforcement structure arranged on the carrier; and
a flexible chip arranged on the carrier supported by the reinforcement structure;
wherein the reinforcement structure increases the stiffness of the chip arrangement.

25. The chip arrangement of claim 24, wherein a first reinforcement structure is arranged on a first side of the carrier and a second reinforcement structure is arranged on a second side of the carrier opposite to the first side of the carrier.

26. The chip arrangement of claim 25, wherein the additional reinforcement structure is at least part of a contact pad structure, wherein the contact pad structure is electrically connected to the chip.

27. A chip arrangement, comprising:
a chip package comprising a flexible chip and at least one reinforcement structure;
a flexible carrier attached to the chip package; and
an antenna structure arranged on the flexible carrier, wherein the antenna structure is electrically conductively connected to the chip;
wherein the reinforcement structure increases the stiffness of the chip arrangement.
